(19) United States
(12) Patent Application Publication
(10) Pub. No.: US 2026/0122850 A1
(43) Pub. Date: Apr. 30, 2026

(54) COOLING UNIT

(71) Applicant: NIDEC CORPORATION, Kyoto (JP)

(72) Inventors: Ikumi KODATE, Kyoto (JP); Yasoya HARA, Kyoto (JP); Masataka MATSUOKA, Kyoto (JP); Kosuke MIZUIKE, Kyoto (JP); Yu TACHIBANA, Kyoto (JP); Shinsuke HAMANO, Kyoto (JP)

(21) Appl. No.: 19/371,079

(22) Filed: Oct. 28, 2025

(30) Foreign Application Priority Data
Oct. 31, 2024 (JP) 2024-191873

(51) Int. Cl. H05K 7/20

(52) U.S. Cl. CPC H05K 7/20272

(57) ABSTRACT

A cooling assembly includes multiple coolant distributors and a control device. The coolant distributors each include a pump, a pressure sensor, and a flow rate sensor. The pump delivers a coolant. The pressure sensor detects a pressure of the coolant. The flow rate sensor detects a flow rate of the coolant. The control device includes a controller. The controller is communicably connected to the multiple coolant distributors, and is configured or programmed to control operation of the multiple coolant distributors in accordance with at least one of detection results of the pressure sensors and detection results of the flow rate sensors which are received from the multiple coolant distributors.

### CROSS-REFERENCE TO RELATED APPLICATIONS

The present application claims priority under 35 U.S.C. § 119 to Japanese Patent Application No. 2024-191873, filed on Oct. 31, 2024, the entire contents of which are hereby incorporated herein by reference.

### 1. FIELD OF THE INVENTION

Example embodiments of the present disclosure relate to cooling assemblies.

### 2. BACKGROUND

There is a cooling g system that cools electronic components using multiple coolant distribution units (CDUs). The CDUs are individually controlled by control devices provided for the respective CDUs.

However, a cooling system that individually controls multiple CDUs has room for improvement in terms of controllability of the entire system.

### SUMMARY

An example embodiment of the present disclosure includes a cooling assembly including multiple coolant distributors and a control device. The coolant distributors each include a pump, a pressure sensor, and a flow rate sensor. The pump delivers a coolant. The pressure sensor detects a pressure of the coolant. The flow rate sensor detects a flow rate of the coolant. The control device includes a controller. The controller is communicably connected to the multiple coolant distributors, and is configured or programmed to control operation of the multiple coolant distributors in accordance with at least one of detection results of the pressure sensors and detection results of the flow rate sensors which are received from the multiple coolant distributors.

The above and other elements, features, steps, characteristics and advantages of the present disclosure will become more apparent from the following detailed description of the example embodiments with reference to the attached drawings.

### BRIEF DESCRIPTION OF THE DRAWINGS

FIG. 1 is an explanatory diagram illustrating a cooling assembly according to an example embodiment of the present disclosure.

FIG. 2 is an explanatory diagram illustrating a coolant distributor according to an example embodiment of the present disclosure.

FIG. 3 is an explanatory diagram illustrating a control device according to an example embodiment of the present disclosure.

FIG. 4 is an explanatory diagram illustrating a display example of a display operator according to an example embodiment of the present disclosure.

FIG. 5 is an explanatory diagram illustrating a display example of the display operator according to an example embodiment of the present disclosure.

FIG. 6 is a flowchart illustrating an example of processing executed by a controller according to an example embodiment of the present disclosure.

FIG. 7 is an explanatory diagram of a cooling assembly according to a modification of an example embodiment of the present disclosure.

### DETAILED DESCRIPTION

Hereinafter, example embodiments of cooling assemblies will be described in detail with reference to the accompanying drawings. Note that, the present disclosure is not limited by the following example embodiments.

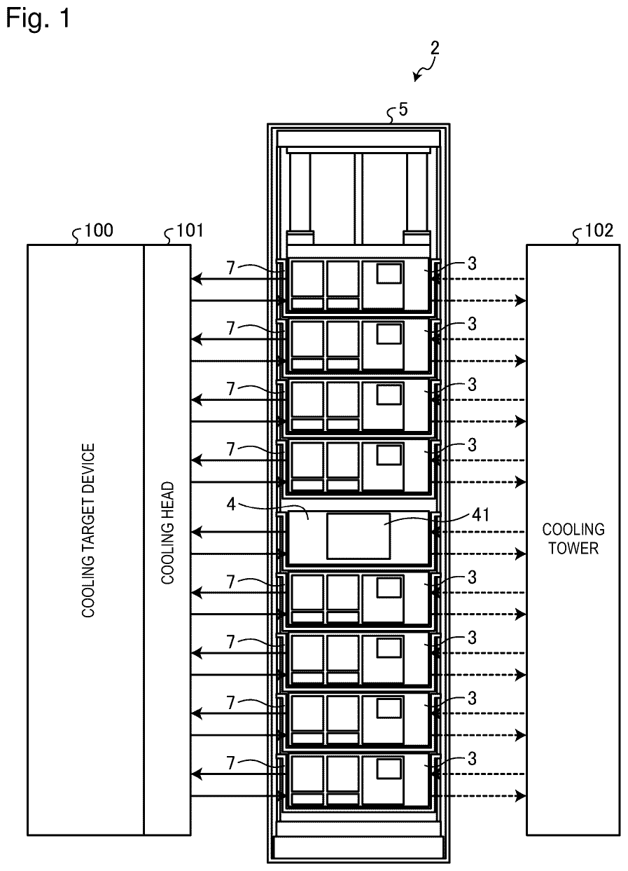

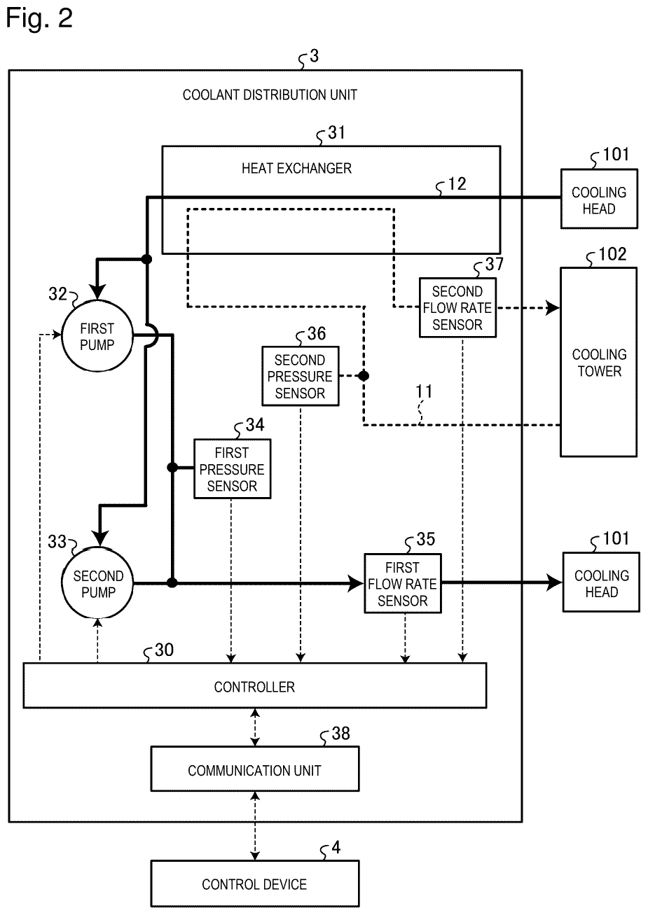

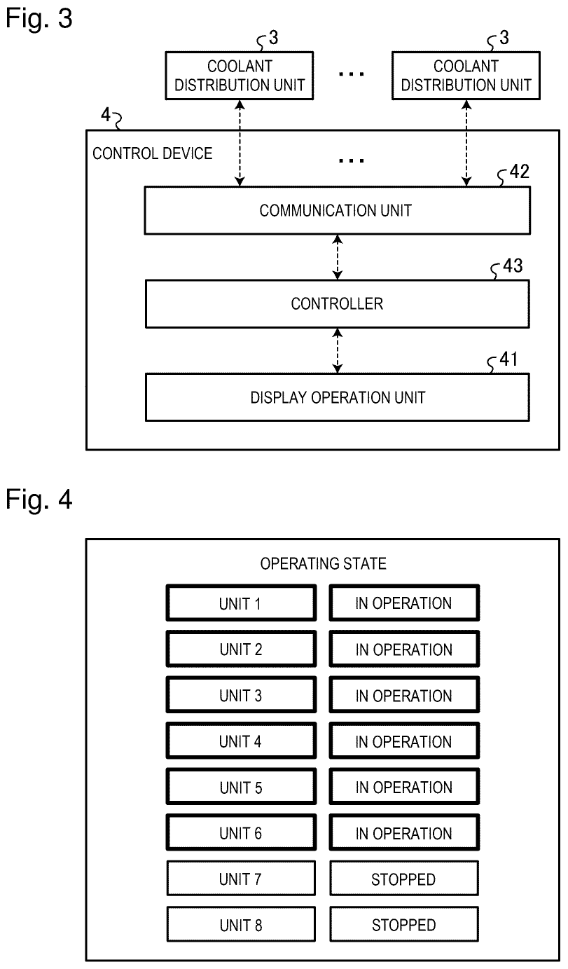

FIG. 1 is an explanatory diagram illustrating a cooling assembly 2 according to an example embodiment of the present disclosure. FIG. 2 is an explanatory diagram illustrating a coolant distributor 3 according to the present example embodiment. FIG. 3 is an explanatory diagram illustrating a control device 4 according to the present example embodiment.

The cooling assembly 2 is a device that cools a cooling target device 100 by exchanging heat between a primary coolant, circulating in a flow path indicated by a thick dotted arrow in FIG. 1, and a secondary coolant circulating in a flow path indicated by a thick solid arrow in FIG. 1.

In one example, the cooling target device 100 is a central processing unit (CPU). A cooling head 101 is attached to the cooling target device 100. The cooling head 101 is provided therein with a circulation flow path for a secondary coolant. The cooling assembly 2 includes multiple coolant distributors 3 and a control device 4. A first pressure sensor 34 is disposed at a position where the pressure of a first pump 32 is detected, but may be disposed at a position where the pressure of a second pump 33 is detected.

As illustrated in FIG. 2, each coolant distributor 3 includes: a heat exchanger 31; the first pump 32; the second pump 33; the first pressure sensor 34; a first flow rate sensor 35; a second pressure sensor 36; and a second flow rate sensor 37. The coolant distributor 3 further includes: a controller 30; a communication unit 38; a primary flow path 11; and a secondary flow path 12.

The controller 30 includes a microcomputer having a CPU, a read only memory (ROM), a random access memory (RAM), and the like, and various circuits. The controller 30 is configured to acquire detection results respectively from the first pressure sensor 34, the second pressure sensor 36, the first flow rate sensor 35, and the second flow rate sensor 37 by causing the CPU to execute a program stored in the ROM using the RAM as a work area. The controller 30 is further configured to control operation of the first pump 32 and the second pump 33. The communication unit 38 is a communication interface that performs information communication with the control device 4.

The primary flow path 11 is a circulation path for a primary coolant that circulates the primary coolant between the coolant distributor 3 and a cooling tower 102. The secondary flow path 12 is a circulation path for a secondary coolant that circulates the secondary coolant between the coolant distributor 3 and the cooling head 101.

The heat exchanger 31 is a device that cools the secondary coolant by causing the primary coolant to absorb heat of the secondary coolant heated by absorbing heat from the cooling target device 100 in the process of flowing through the cooling head 101. The primary coolant heated by absorbing heat of the secondary coolant in the heat exchanger 31 is sent to the cooling tower 102, cooled in the cooling tower 102, and then sent to the heat exchanger 31 again.

The first pump 32 and the second pump 33 are pumps that are provided in the secondary flow path 12 and deliver the secondary coolant to the cooling head 101. The first pressure sensor 34 is a sensor that is provided in the secondary flow path 12 and detects the pressure of the secondary coolant flowing through the secondary flow path 12. In one example, the first pressure sensor 34 is disposed at a position where the pressure at the junction of the output of the first pump 32 and the output of the second pump 33 is measured. The first pressure sensor 34 outputs a detection result to the controller 30. The controller 30 acquires the detection result from the first pressure sensor 34.

The first flow rate sensor 35 is a sensor that is provided in the secondary flow path 12 and detects the flow rate of the secondary coolant flowing through the secondary flow path 12. The first flow rate sensor 35 outputs a detection result to the controller 30. The controller 30 acquires the detection result from the first flow rate sensor 35. The second pressure sensor 36 is a sensor that is provided in the primary flow path 11 and detects the pressure of the primary coolant flowing through the primary flow path 11.

The second pressure sensor 36 outputs a detection result to the controller 30. The controller 30 acquires the detection result from the second pressure sensor 36. The second flow rate sensor 37 is a sensor that is provided in the primary flow path 11 and detects the flow rate of the primary coolant flowing through the primary flow path 11. The second flow rate sensor 37 outputs a detection result to the controller 30. The controller 30 acquires the detection result from the second flow rate sensor 37.

Then, the controller 30 transmits the detection results, obtained by the first pressure sensor 34, the first flow rate sensor 35, the second pressure sensor 36, and the second flow rate sensor 37, to the control device 4 via the communication unit 38. In addition, the controller 30 outputs a control signal, received from the control device 4 via the communication unit 38, to the first pump 32 and the second pump 33.

Further, although not illustrated in FIG. 2, each coolant distributor 3 includes a touch panel display that can manually change the settings of the first pump 32 and the second pump 33, for example. The controller 30 outputs a control signal, corresponding to a user's operation on the touch panel display, to first pump 32 and second pump 33.

Note that, each coolant distributor 3 may have a configuration not including the controller 30. In this case, the first pressure sensor 34, the first flow rate sensor 35, the second pressure sensor 36, and the second flow rate sensor 37 transmit the respective detection results to the control device 4 via the communication unit 38. In addition, a control signal received from the control device 4 by the communication unit 38 is input to the first pump 32 and the second pump 33.

As illustrated in FIG. 3, the control device 4 includes: a display operator 41; a communication unit 42; and a controller 43. The control device 4 and each of the coolant distributors 3 are separate bodies. Thus, the control device 4 has a configuration in which no flow path for a coolant is provided inside the housing of the control device 4. As a result, the control device 4 can suppress a failure of the control device 4 which would otherwise be caused by leakage of a coolant or the like.

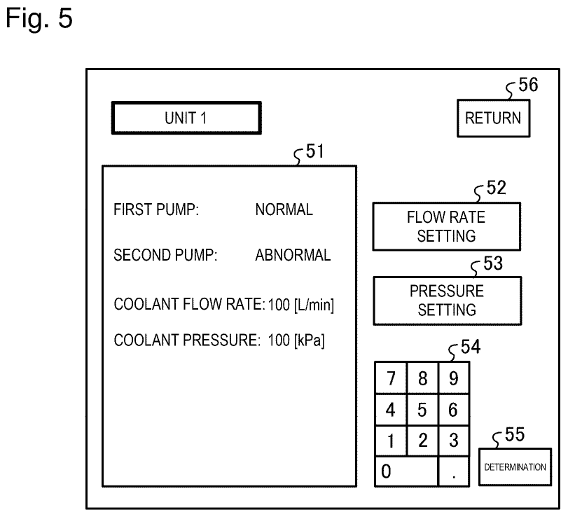

The display operator 41 is, for example, a touch panel display. The display operator 41 is configured to display various types of information. An example of a display screen displayed by the display operator 41 will be described later with reference to FIG. 4 and FIG. 5. In addition, the display operator 41 receives a touch operation by the user, and outputs an operation signal corresponding to the touch operation to controller 43.

In the display operator 41 of the control device 4, the size of the touch panel display is larger than the size of the touch panel display of each coolant distributor 3. Thus, the display operator 41 of the control device 4 can have improved operability relative to the touch panel display of each coolant distributor 3.

Note that, the display operator 41 of the control device 4 may have a configuration such that the size of the touch panel display is equal to the size of the touch panel display of each coolant distributor 3. In this case, the display operator 41 of the control device 4 is disposed so that the installation position of the control device 4 in is housing is the same as the installation position of each coolant distributor 3 in its housing.

As a result, the visibility of the display operator 41 of the control device 4 by the user is improved. For example, by making display of the touch panel display of the coolant distributors 3 so that the display contents can be checked in a page flipping manner, the position of the display contents of the display operator 41 of the control device 4 matches with the position of the display contents of the coolant distributors 3 displayed in a page flipping manner, thereby improving visibility.

The communication unit 42 is a communication interface that performs information communication with the multiple coolant distributors 3. The communication unit 42 receives detection results, obtained by the first pressure sensor 34, the first flow rate sensor 35, the second pressure sensor 36, and the second flow rate sensor 37, from the multiple coolant distributors 3 and outputs the detection results to the controller 43. In addition, the communication unit 42 transmits a control signal, input from the controller 43, to the multiple coolant distributors 3.

The controller 43 includes a microcomputer having a CPU, a ROM, a RAM, and the like, and various circuits. The controller 43 is configured to control operation of the multiple coolant distributors 3 and the display operator 41 by causing the CPU to execute a program stored in the ROM using the RAM as a work area.

In one example, the controller 43 is communicably connected to the multiple coolant distributors 3 via the communication unit 42. The controller 43 controls operation of the multiple coolant distributors 3 in accordance with at least one of the detection results of the first pressure sensors 34 and the detection results of the first flow rate sensors 35 which are received from the multiple coolant distributors 3. As a result, the cooling assembly 2 can control all of the multiple coolant distributors 3 by one control device 4, so that controllability of the entire system can be improved.

Specifically, the controller 43 controls operation of the first pump 32 and the second pump 33 to bring a total value of the detection results of the first flow rate sensors 35, received from the multiple coolant distributors 3, close to the flow rate set by the user. As a result, the cooling assembly 2 can bring the flow rate of the secondary coolant close to the flow rate desired by the user by using the multiple coolant distributors 3.

In addition, the controller 43 controls operation of the first pump 32 and the second pump 33 to bring the detection results of the first flow rate sensors 35, received from the multiple coolant distributors 3, close to the equivalent detection results. Accordingly, the cooling assembly 2 can suppress concentration of a load on some of the multiple coolant distributors 3.

Further, the controller 43 detects abnormality of the coolant distributor 3 based on at least one of the detection result of the first pressure sensor 34 and the detection result of the first flow rate sensor 35. For example, when the difference between the pressure of the secondary coolant detected by the first pressure sensor 34 and the set value of the pressure exceeds a threshold, the controller 43 determines that the coolant distributor 3 including the first pressure sensor 34 having transmitted this detection result is abnormal.

Meanwhile, when the difference between the flow rate of the secondary coolant detected by the first flow rate sensor 35 and the set value of the flow rate exceeds a threshold, the controller 43 determines that abnormality occurs in any one of the operating coolant distributors 3.

Note that, the controller 43 can also determine abnormality of each coolant distributor 3 based on information other than the detection results of the first pressure sensor 34 and the first flow rate sensor 35. For example, the controller 43 can determine abnormality of each coolant distributor 3 based on information on another operation state of the coolant distributor 3, such as a case where communication with the coolant distributor 3 is interrupted or a case where power supply to the coolant distributor 3 is interrupted.

In a case where the controller 43 has successfully identified the coolant distributor 3 whose abnormality has been detected, the controller 43 controls operation of the first pump 32 and the second pump 33 of another coolant distributor 3, whose abnormality has not been detected, to compensate for the amount of delivery of the secondary coolant.

In addition, in a case where the controller 43 has determined that any one of the coolant distributors 3 has abnormality, if there is any coolant distributor 3 not operating, the controller 43 operates this coolant distributor 3 to compensate for the amount of delivery of the secondary coolant. As a result, even when abnormality occurs in any of the coolant distributors 3, the cooling assembly 2 can bring the flow rate of the secondary coolant close to the flow rate desired by the user.

Next, an example of the display screen displayed by the display operator 41 of the control device 4 will be described with reference to FIG. 4 and FIG. 5. FIG. 4 and FIG. 5 are explanatory diagrams illustrating a display example of the display operator 41 according to the present example embodiment.

As illustrated in FIG. 4, the controller 43 displays a state display screen indicating an operating state of each of the coolant distributors 3 while the control device 4 is powered on. The coolant distributors 3 surrounded by a thick frame on the state display screen are the operating coolant distributors 3.

The example illustrated in FIG. 4 indicates that six coolant distributors 3 of Units 1 to 6 are in operation and two coolant distributors 3 of Units 7 and 8 are stopped. Accordingly, the user of the cooling assembly 2 can check the operating states of all the coolant distributors 3 by checking the state display screen without individually checking the operating states of the coolant distributors 3.

In addition, by touching an operation button displayed as being stopped on the state display screen, the user can operate the coolant distributor 3 displayed next to the operation button. For example, by touching an operation button displayed as being stopped next to Unit 7 on the state display screen, the user can operate Unit 7 being stopped.

Meanwhile, by touching an operation button displayed as in operation on the state display screen, the user can stop the coolant distributor 3 displayed next to the operation button. For example, by touching an operation button displayed as in operation next to Unit 1 on the state display screen, the user can stop Unit 1 in operation. In other words, the user can set the number of coolant distributors 3 to be operated by operating the state display screen.

As described above, the control device 4 includes the display operator 41 that receives an operation to set the number of the coolant distributors 3 to be operated. The controller 43 operates the coolant distributors 3 as many as the number set by the operation of the display operator 41. Accordingly, the user can change the number of coolant distributors 3 to be operated as necessary.

Further, when an operation to select the operating coolant distributor 3 displayed on the state display screen is performed, the controller 43 displays a setting screen of the selected coolant distributor 3. For example, when an operation button displayed as Unit 1 on the state display screen is operated, the controller 43 displays a setting screen of the coolant distributor 3 of Unit 1 illustrated in FIG. 5.

As illustrated in FIG. 5, the display screen of Unit 1 includes: a state display area 51 in which the states of the first pump 32 and the second pump 33 of Unit 1, the detection result of the first flow rate sensor 35 of Unit 1, and the detection result of the first pressure sensor 34 of Unit 1 are displayed; a flow rate setting button 52; a pressure setting button 53; numeric keypad buttons 54; a determination button 55; and a return button 56.

As a result, the user can check the operation state of Unit 1 by visually recognizing the state display area 51. In addition, the user can change the setting of the flow rate of the secondary coolant by touching the flow rate setting button 52, then operating the numeric keypad buttons 54 to input a desired flow rate of the secondary coolant, and then touching the determination button 55.

Further, the user can change the setting of the pressure of the secondary coolant by touching the pressure setting button 53, then operating the numeric keypad buttons 54 to input a desired pressure of the secondary coolant, and then touching the determination button 55. Thereafter, when the return button 56 in the state display area 51 is touched, the controller 43 displays the state display screen illustrated in FIG. 4.

For example, the controller 43 may display a screen for inputting a coolant pressure threshold on the state display screen (such as the screen illustrated in FIG. 5) indicating the operating state of each of the coolant distributors 3. In this case, the controller 43 displays an alarm for the coolant distributor 3 operating at a coolant pressure exceeding the threshold or falling below the threshold.

Meanwhile, when a failure occurs in the coolant distributor 3, the controller 43 causes the touch panel display of the target coolant distributor 3 and the display operator 41 of the control device 4 to display an alarm indicating the occurrence of the failure. When a failure occurs only in the control device 4, the controller 43 causes only the display operator 41 of the control device 4 to display an alarm indicating the occurrence of the failure. As a result, the user can easily check the alarm display.

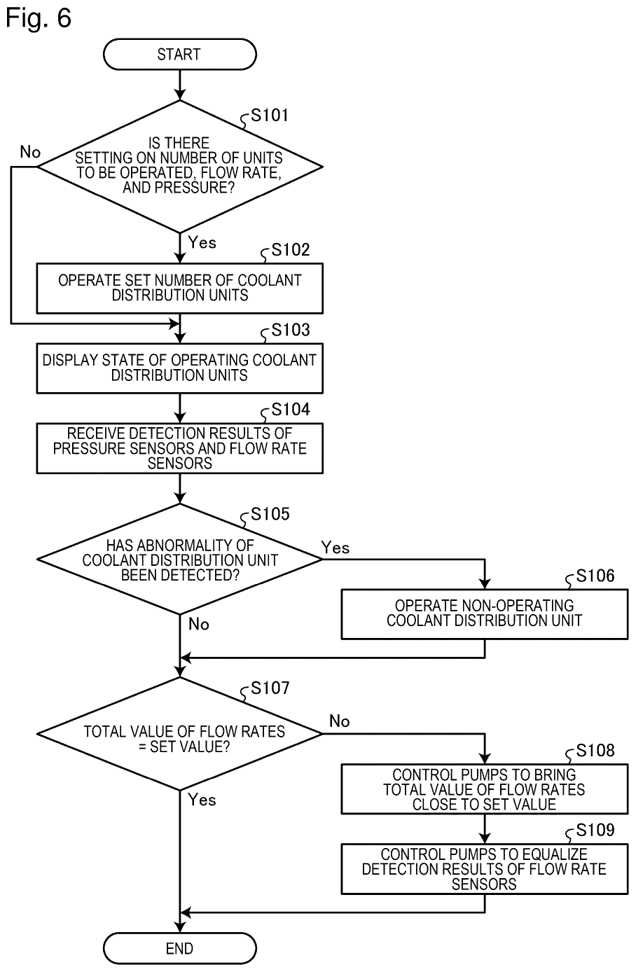

Next, processing executed by the controller 43 will be described with reference to FIG. 6. FIG. 6 is a flowchart illustrating an example of processing executed by the controller 43 according to the present example embodiment. The controller 43 repeatedly executes the processing illustrated in FIG. 6 while the control device 4 is powered on.

Specifically, the controller 43 first determines whether or not there is an operation to set the number of coolant distributors 3 to be operated, the flow rate of the secondary coolant, or the pressure of the secondary coolant (Step S101). If the controller 43 determines that there is no setting operation (Step S101, No), the processing moves to Step S103.

Meanwhile, if the controller 43 determines that there is a setting operation (Step S101, Yes), the controller 43 operates the set number of coolant distributors 3 (Step S102). At this time, the controller 43 controls the first pump 32 and the second pump 33 to bring the flow rate and the pressure of the secondary coolant close to the settings.

Then, the controller 43 causes the display operator 41 to display the state of the operating coolant distributors 3 (Step S103). Subsequently, the controller 43 receives detection results of the respective first pressure sensors 34 and the respective first flow rate sensors 35 (Step S104).

Then, based on the received detection results, the controller 43 determines whether abnormality of the coolant distributor 3 has been detected (Step S105). If the controller 43 determines that the abnormality of the coolant distributor 3 has been detected (Step S105, Yes), the controller 43 operates the non-operating coolant distributor 3 (Step S106) to compensate for the flow rate of the secondary coolant, and moves the processing to Step S107.

Meanwhile, if the controller 43 determines that no abnormality of the coolant distributor 3 has been detected (Step S105, No), the controller 43 determines whether the total value of the flow rates of the secondary coolant received from the respective first flow rate sensors 35 is equal to the set value of the flow rate (Step S107).

If the controller 43 determines that the total value of the received flow rates of the secondary coolant is equal to the set value of the flow rate (Step S107, Yes), the controller 43 ends the current processing and starts processing from Step S101.

Meanwhile, if the controller 43 determines that the total value of the received flow rates of the secondary coolant is not equal to the set value of the flow rate (Step S107, No), the controller 43 controls the first pump 32 and the second pump 33 to bring the total value of the flow rates of the secondary coolant close to the set value of the flow rate (Step S108).

Further, the controller 43 controls the first pump 32 and the second pump 33 to equalize the detection results of the respective first flow rate sensors 35 (Step S109), ends the current processing, and starts processing from Step S101.

Next, returning to FIG. 1, the arrangement and the like of the multiple coolant distributors 3 will be described. As illustrated in FIG. 1, the multiple coolant distributors 3 and the control device 4 are housed in the same rack 5. As a result, another installation location of the control device 4 does not need to be secured in the cooling assembly 2 separately from the installation location of the coolant distributors 3, so that the installation space can be reduced.

In addition, the multiple coolant distributors 3 are arranged in the longitudinal direction of the rack 5. The control device 4 is disposed at a position sandwiched between the coolant distributors 3 arranged in the longitudinal direction of the rack 5. As a result, in the cooling assembly 2, the length of wiring connecting the control device 4 and the coolant distributors 3 can be shortened as compared with the case where the control device 4 is provided at the end of the row of the coolant distributors 3.

Further, when the control device 4 is disposed at a position sandwiched between the coolant distributors 3 arranged in the longitudinal direction of the rack 5, the control device 4 is preferably disposed at the center of the row of the coolant distributors 3. As a result, in the cooling assembly 2, the length of wiring connecting the coolant distributor 3, disposed at the farthest position from the control device 4, and the control device 4 can be minimized.

Additionally, the rack 5 includes multiple drawers 7 into which the respective coolant distributors 3 are inserted. The control device 4 is inserted into one of the multiple drawers 7 and stored in the rack 5. As a result, in the cooling assembly 2, flexibility in the installation position of the control device 4 in the rack 5 is enhanced. Thus, for example, the user can install the control device 4 in such a way as to insert the control device 4 into the drawer 7 located at a height at which the display operator 41 of the control device 4 is easily visible.

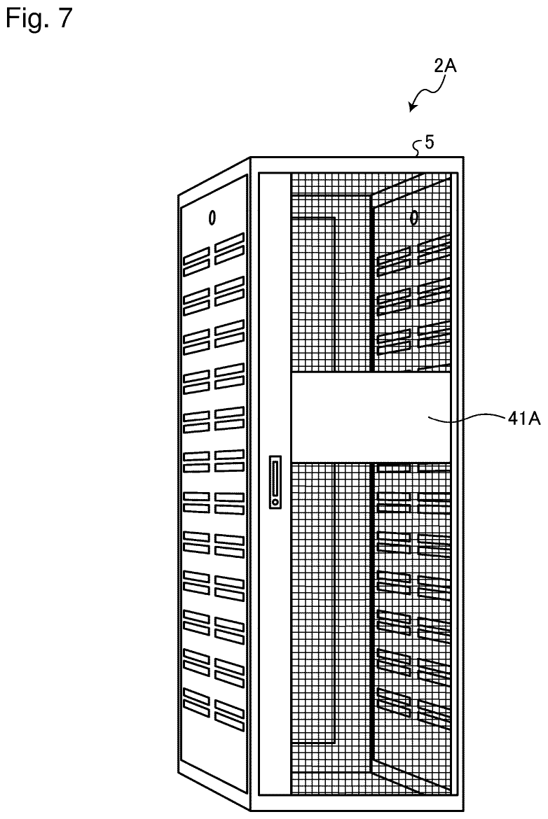

Note that, the configuration of the control device 4 illustrated in FIG. 3 is an example, and various modifications are possible. FIG. 7 is an explanatory diagram of a cooling assembly 2A according to a modification of the example embodiment. As illustrated in FIG. 7, a display operator 41A of the control device 4 may be provided on a door of the rack 5. This enables the user to check the states of the multiple coolant distributors 3 from the outside of the rack 5 without opening the door of the rack 5.

Example embodiments of the present disclosure can have configurations as described below.

(1) A cooling assembly including multiple coolant distributors each including a pump to deliver a coolant, a pressure sensor to detect a pressure of the coolant, and a flow rate sensor to detects a flow rate of the coolant, and a control device including a controller communicably connected to the multiple coolant distributors and configured or programmed to control operation of the multiple coolant distributors in accordance with at least one of detection results of the pressure sensors and detection results of the flow rate sensors which are received from the multiple coolant distributors.

(2) The cooling assembly according to (1) above, in which the multiple coolant distributors and the control device are housed in a same rack.

(3) The cooling assembly according to (2) above, in which the multiple coolant distributors are arranged in a longitudinal direction of the rack, and the control device is at a position between a pair of the coolant distributors.

(4) The cooling assembly according to any one of (1) to (3) above, in which the controller is configured or programmed to control operation of the pump to bring a total value of the detection results of the flow rate sensors, received from the multiple coolant distributors, close to a flow rate set by a user.

(5) The cooling assembly according to any one of (1) to (4) above, in which the control device includes an operator to receive an operation to set a number of the coolant distributors to be operated, and the controller operates the set number of the coolant distributors set by the operation of the operator.

(6) The cooling assembly according to any one of (1) to (5) above, in which in a case where the controller detects abnormality of any of the coolant distributors based on at least one of the detection results of the pressure sensors and the detection results of the flow rate sensors, the controller is configured or programmed to control operation of the pump of another one of the coolant distributors, whose abnormality is not detected, to compensate for an amount of delivery of the coolant.

(7) The cooling assembly according to any one of (1) to (6) above, in which the controller is configured or programmed to control operation of the pump to bring the detection results of the flow rate sensors, received from the multiple coolant distributors, close to equivalent detection results.

(8) The cooling assembly according to any one of (1) to (7) above, in which the control device includes a display to displays information on a state of each of the coolant distributors.

(9) The cooling assembly according to (2) or (3) above, in which the control device includes a display to display information on a state of each of the coolant distributors, and the display is on a door of the rack.

(10) The cooling assembly according to (2) or (3) above, in which the rack includes multiple drawers into which the coolant distributors are inserted, and the control device is inserted into any of the drawers.

Further effects and modifications can be easily derived by those skilled in the art. Thus, example embodiments of the present disclosure are not limited to the specific details and the representative example embodiments presented and described above. Accordingly, various changes may be made without departing from the spirit or scope of the general inventive concepts as defined by the appended claims and their equivalents.

Features of the above-described example embodiments and the modifications thereof may be combined appropriately as long as no conflict arises.

While example embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. A cooling assembly comprising:
multiple coolant distributors each including a pump to deliver a coolant, a pressure sensor to detect a pressure of the coolant, and a flow rate sensor to detect a flow rate of the coolant; and
a control device including a controller communicably connected to the multiple coolant distributors and configured or programmed to control operation of the multiple coolant distributors in accordance with at least one of detection results of the pressure sensors and detection results of the flow rate sensors which are received from the multiple coolant distributors.

2. The cooling assembly according to claim 1, wherein the multiple coolant distributors and the control device are housed in a same rack.

3. The cooling assembly according to claim 2, wherein
the multiple coolant distributors are arranged in a longitudinal direction of the rack; and
the control device is between a pair of the coolant distributors.

4. The cooling assembly according to claim 1, wherein the controller is configured or programmed to control operation of the pump to bring a total value of the detection results of the flow rate sensors, received from the multiple coolant distributors, close to a flow rate set by a user.

5. The cooling assembly according to claim 1, wherein
the control device includes an operator to receive an operation to set a number of the coolant distributors to be operated; and
the controller operates the set number of the coolant distributors set by the operation of the operator.

6. The cooling assembly according to claim 1, wherein in a case where the controller detects abnormality of any of the coolant distributors based on at least one of the detection results of the pressure sensors and the detection results of the flow rate sensors, the controller is configured or programmed to control operation of the pump of another one of the coolant distributors, whose abnormality is not detected, to compensate for an amount of delivery of the coolant.

7. The cooling assembly according to claim 1, wherein the controller is configured or programmed to control operation of the pump to bring the detection results of the flow rate sensors, received from the multiple coolant distributors, close to equivalent detection results.

8. The cooling assembly according to claim 1, wherein the control device includes a display to display information on a state of each of the coolant distributors.

9. The cooling assembly according to claim 2, wherein
the control device includes a display to display information on a state of each of the coolant distributors; and
the display is on a door of the rack.

10. The cooling assembly according to claim 2, wherein
the rack includes multiple drawers into which the coolant distributors are inserted; and
the control device is inserted into any of the drawers.
